(19) United States
(12) Patent Application Publication
(10) Pub. No.: US 2014/0318742 A1
(43) Pub. Date: Oct. 30, 2014

(54) Cooling Device with Bypass Channel

(71) Applicant: TM4 INC., Boucherville (CA)

(72) Inventors: Martin Houle, Laval (CA); Stephane Poulin, Sainte-Julie (CA)

(21) Appl. No.: 14/110,401

(22) PCT Filed: Mar. 28, 2012
(86) PCT No.: PCT/CA2012/000324

§ 371 Date: Dec. 5, 2013

Related U.S. Application Data
(60) Provisional application No. 61/474,819, filed on Apr. 13, 2011.

(51) Int. Cl. H05K 7/20

(52) U.S. Cl. CPC H05K 7/20263
USPC 165/80.4; 165/104.33

(57) ABSTRACT

A cooling device to which an electric circuit may be mounted includes a cooling body and a cover both defining a fluid cooling path. Inner and outer seals are provided between the body and the cover and a leak bypass channels leaking fluid away from the electric circuit is provided between the inner and outer seals.

### FIELD

The present disclosure relates to cooling devices. More specifically, the present disclosure is concerned with a cooling device to which an electric circuit is to be mounted and provided with a bypass channel.

### BACKGROUND

Cooling devices are well known in the art of electric circuits. They are usually designed to collect heat generated by one or more electronic components and dissipate this collected heat away from the electronic components to thereby improve their performance or, in some cases, allow them to function properly.

Fluids are often used to collect the heat and to transfer it from the vicinity of the electronic components to the vicinity of the dissipating element. A drawback with the use of fluid to collect and transfer the heat is the risks of developing a leak that would bring electric conducting cooling fluid in contact with the electronic components.

### BRIEF DESCRIPTION OF THE DRAWINGS

In the appended drawings:

FIG. 1 is a top plan view of a cooling device according to a first illustrative embodiment;

FIG. 2 is an inside view of a cover part of the cooling device of FIG. 1;

FIG. 3 is a sectional view of the cooling device taken along line 3-3 of FIG. 1;

FIG. 4 is a sectional view of the cooling device taken along line 4-4 of FIG. 1;

FIG. 5 is a sectional perspective view of the cooling device of FIG. 1 illustrating the fluid inlet;

FIG. 6 is a top plan view of the cover part of a cooling device according to a second illustrative embodiment;

FIG. 7 is a sectional view taken along line 7-7 of FIG. 6;

FIG. 8 is a top plan view of a cooling device according to a third illustrative embodiment; and

FIG. 9 is a sectional view taken along line 9-9 of FIG. 8.

### DETAILED DESCRIPTION

The use of the word “a” or “an” when used in conjunction with the term “comprising” in the claims and/or the specification may mean “one”, but it is also consistent with the meaning of “one or more”, “at least one”, and “one or more than one”. Similarly, the word “another” may mean at least a second or more.

As used in this specification and claim(s), the words “comprising” (and any form of comprising, such as “comprise” and “comprises”), “having” (and any form of having, such as “have” and “has”), “including” (and any form of including, such as “include” and “includes”) or “containing” (and any form of containing, such as “contain” and “contains”), are inclusive or open-ended and do not exclude additional, unrecited elements or process steps.

In the present specification in the appended claims, various terminology which is directional, geometrical and/or spatial in nature such as “longitudinal”, “horizontal”, “front”, rear”, “upwardly”, “downwardly”, etc. is used. It is to be understood that such terminology is used for ease of description and in a relative sense only and is not to be taken in any way as a limitation upon the scope of the present disclosure.

In the present description and in the appended claims, the expression “electric circuit” is to be construed as meaning either discrete electronic components or multiple electric components mounted to a board.

Other objects, advantages and features of the cooling device provided with a bypass channel will become more apparent upon reading of the following non-restrictive description of illustrative embodiments thereof, given by way of example only with reference to the accompanying drawings.

According to an illustrative embodiment, there is provided a cooling device for an electric circuit; said cooling device comprising:

a body;

a cover so configured and sized to be mounted to the body, the cover defining, with the body, a fluid cooling path;

inner and outer seals provided between the cover and the body to prevent fluid from egressing the fluid cooling path;

wherein one of the body and cover is provided with a leak bypass, provided between the inner and outer seals, that collects and channels leaking fluid.

Generally stated, the illustrative embodiments described herein proposes to use a cooling body having an electric circuit receiving surface and constructed in two layers, i.e. a body and a cover, defining a cavity therebetween. A cooling path is provided in the cavity. The junction of the two layers is sealed with inner and outer spaced apart O-rings and is provided with a bypass channel provided between the inner and outer O-rings. The bypass channel and the outer O-ring provide a leaking path should a leak develop in the inner O-ring.

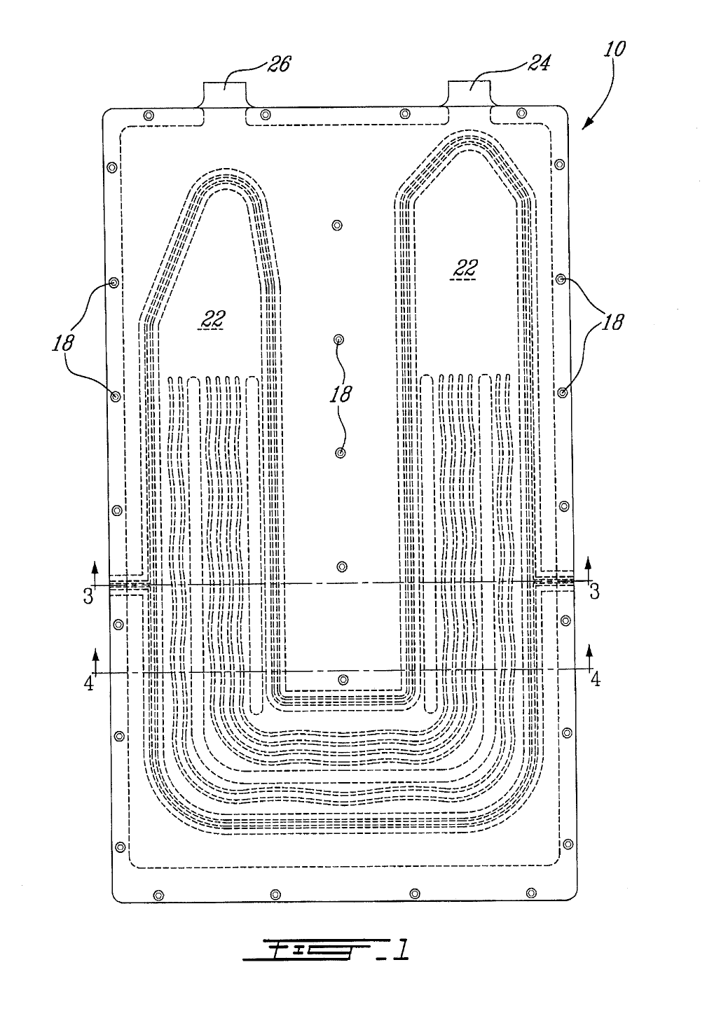

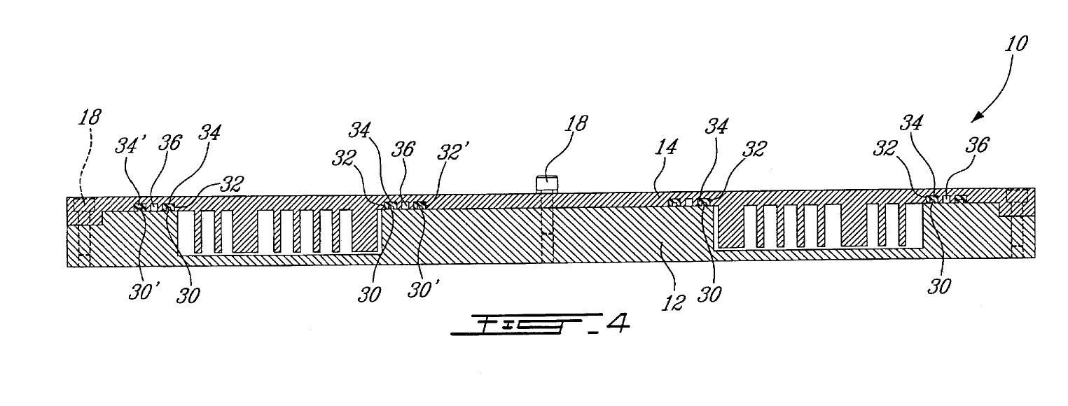

FIGS. 1 to 5 illustrate a cooling device 10 according to a first illustrative embodiment.

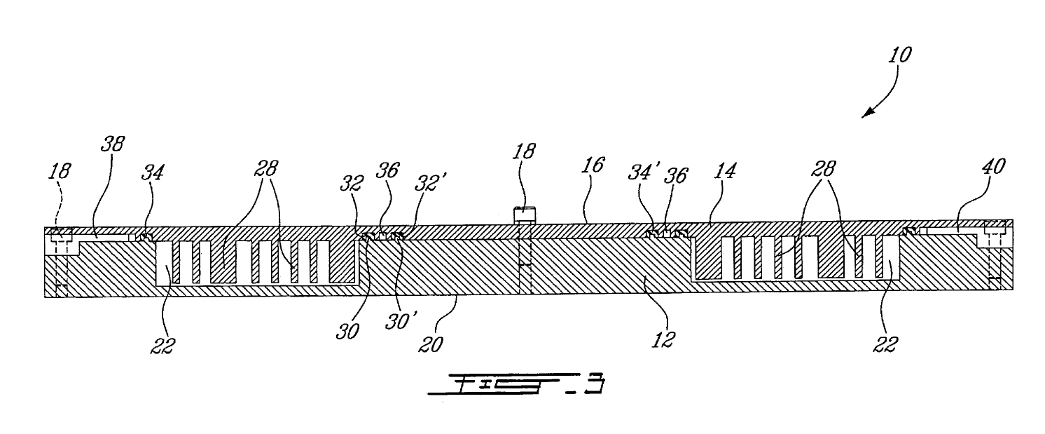

As can be better seen from FIG. 3, the cooling device 10 includes a generally planar body 12 and a generally planar cover 14 having a circuit receiving surface 16. The cover 14 is mounted to the body 12 via a plurality of fasteners 18.

One or many electric circuits (not shown) may be mounted to the surface 16 via fasteners (also not shown). The electric circuits may also be mounted to the underside 20 of the body 12.

The body 12 and cover 14 are each made of a single piece of heat conductive material, such as for example aluminum, that may be machined or otherwise formed into the desired shape.

The body 12 includes a relatively wide fluid cooling channel 22 having a U-shape cross-section as can be seen in FIG. 3 and defining a U-shape fluid channel 22 as can be seen in FIG. 1. A fluid inlet 24 and a fluid outlet 26 are provided in the body 12 and will be described hereinbelow.

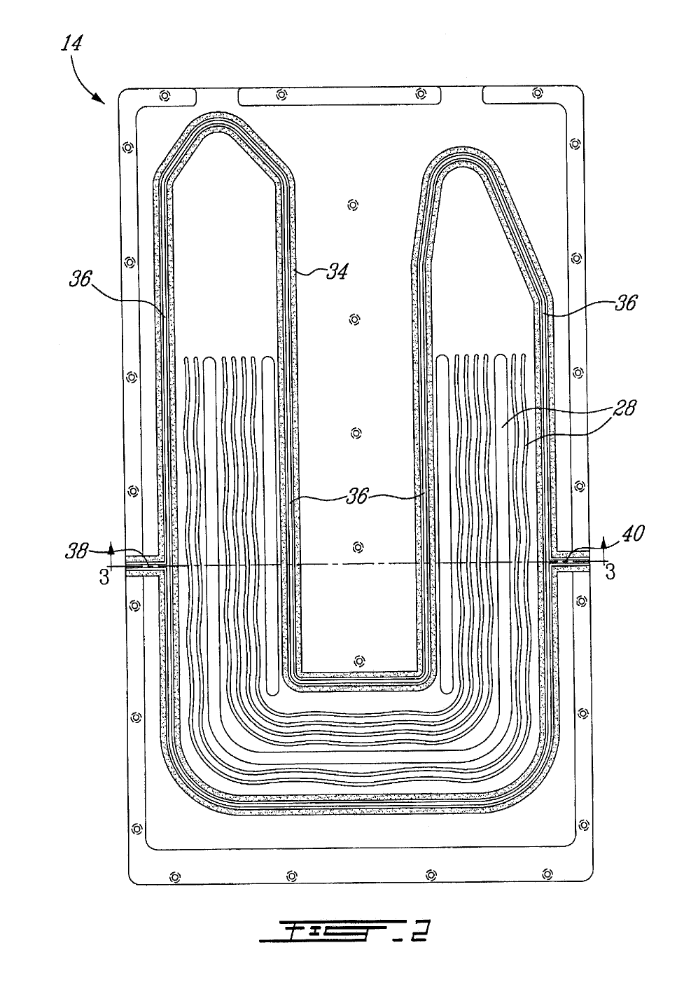

The cover 14 includes fins 28 configured and sized to enter the cooling channel 22 as can be seen in FIG. 3. These fins 28 may also be seen from FIG. 2 illustrating the underside of the cover 14.

When the cover 14 is assembled to the body 12 as illustrated in FIG. 3, a fluid cooling path is defined.

The periphery of the fluid cooling channel 22 is provided with a continuous projection 30 and the cover 14 is provided with a corresponding channel 32, which has larger dimensions to allow a seal, in the form of an inner O-ring 34, to be inserted therebetween.

The O-ring 34 is therefore compressed between the cover 14 and the body 12 to prevent leaks of the cooling fluid.

The cooling device 10 is also provided with a second safety feature to prevent eventual leaking cooling fluid to reach the electric circuits mounted to the surfaces 16 and/or 20.

This second safety feature takes the form of a bypass channel 36 providing a leaking path should a leak develop in the inner O-ring 34 is also provided on the undersurface of the cover 14.

The bypass channel 36 follows the periphery of the channel 22, thereby encircling the channel 22 and the inner O-ring 34. Two leak bypasses 38 and 40 are laterally provided on the underside of the cover 14 and are in connection with the bypass channel 36 to allow leaking fluid to egress the cooling device 10 without damaging the electric circuits (not shown). These lateral leak bypasses 38 and 40 may also be viewed in FIG. 3.

The cooling device 10 is also provided with a third safety feature to prevent eventual leaking cooling fluid to reach the electric circuits mounted to the surfaces 16 and/or 20.

This third safety feature takes the form of a outer O-ring 34′ ensuring that the liquid entering the bypass channel 36 reaches the leak bypasses 38 and 40 without leaking elsewhere.

The periphery of the bypass channel 36 is thus provided with a projection 30′, and the cover 14 is provided with a corresponding channel 32′, which has larger dimensions to allow a seal, in the form of the second O-ring 34′, to be inserted therebetween. Of course, the second O-ring 34′ is not continuous and has portions on both sides of the leak bypasses 38 and 40.

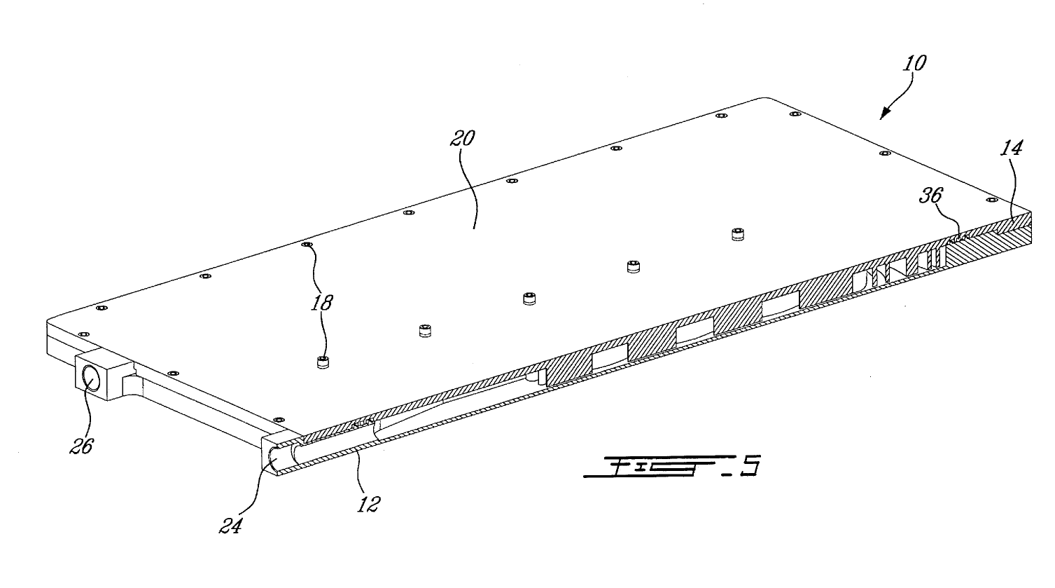

Turning to FIG. 5, which is a sectional view illustrating the inlet 24, it will be apparent to one skilled in the art that the inlet 24 is entirely done in the body 12 and therefore does not require a dedicated seal between the body 12 and the cover 14.

It is to be noted that while the body of the cooling device is shown herein as having a generally rectangular circuit receiving surface 14, other surface shapes could be used, depending on the application.

It is also to be noted that while the seal between the cover and the body has been described hereinabove as being O-rings, other types of seals could be used.

It is also to be noted that the wavy nature of the fins 28 is not essential and that other types of fins could be used. Of course, other schemes to increase the contact surface between the water and the walls of the cooling path could be used.

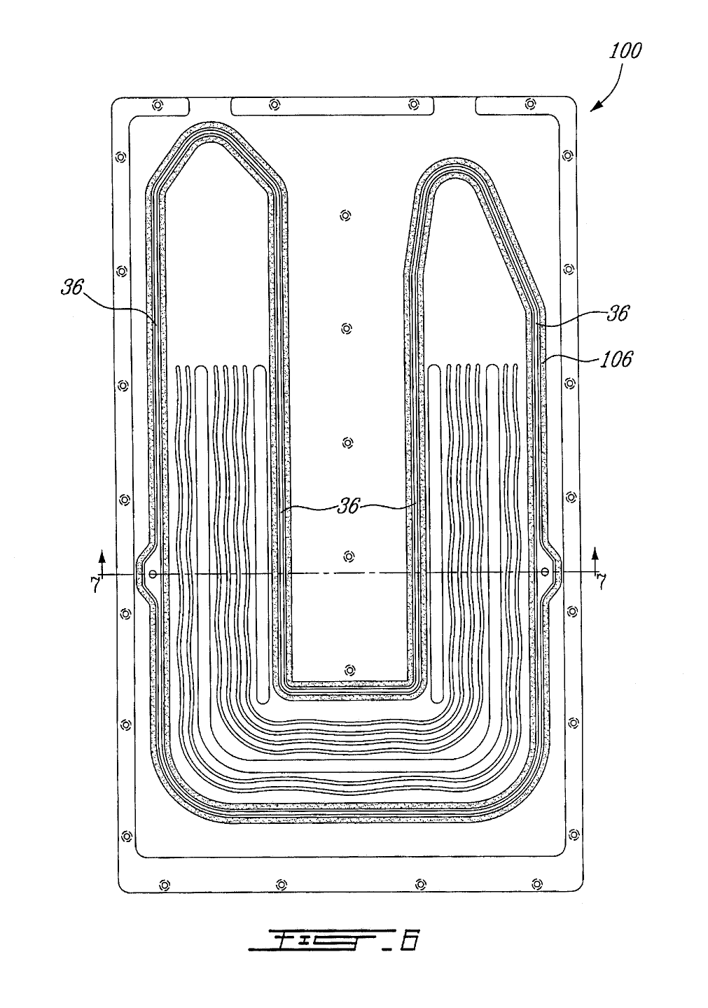

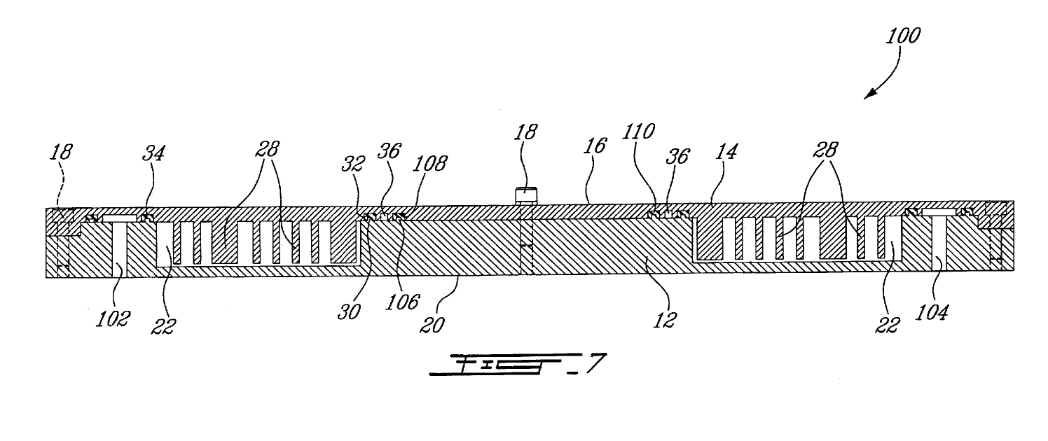

Turning now to FIGS. 6 and 7 of the appended drawings, a cooling device 100 according to a second illustrative embodiment will be described. Since the cooling device 100 is very similar to the cooling device 10 described hereinabove, and for concision purpose, only the differences therebetween will be described hereinbelow.

Generally stated, a main difference between the cooling assemblies 10 and 100 concerns the two leak bypasses 102 and 104 that are defined as through holes going through the entire thickness of the body 12 instead of being laterally provided as illustrated in FIG. 2. This allows the projection 106, the cavity 108 and the outer O-ring 110 to be continuous.

Of course, one skilled in the art will understand that the electric circuits (not shown) are intended to be mounted to the surface 16 only.

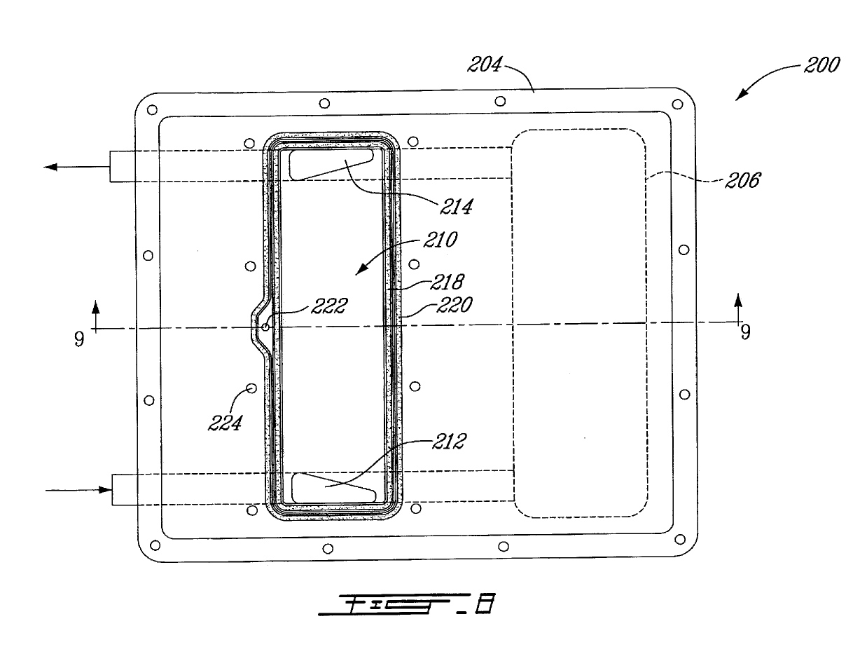

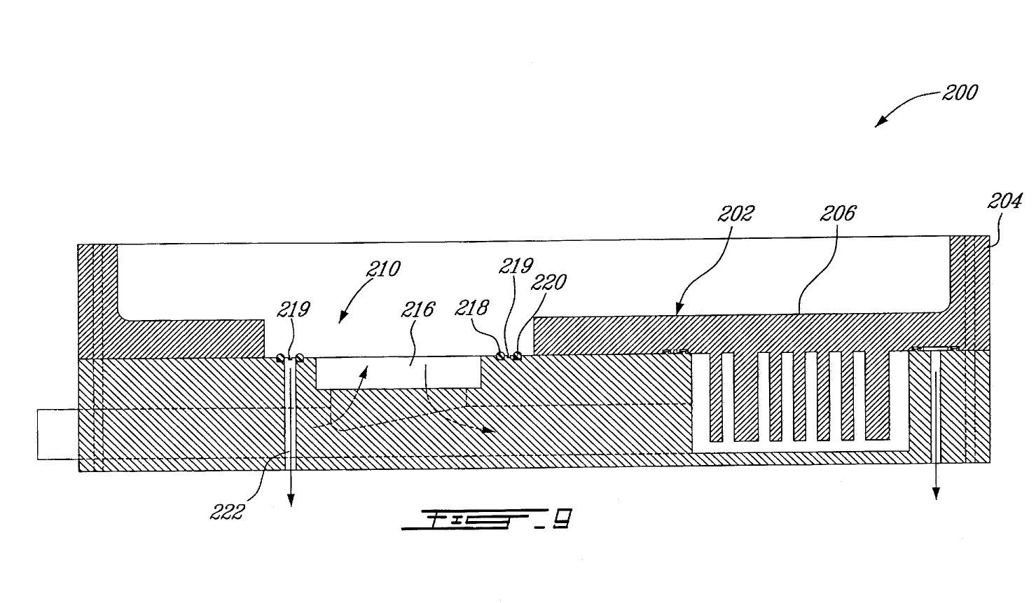

Turning now to FIGS. 8 and 9 of the appended drawings, a cooling device 200 according to a third illustrative embodiment will be described.

The cooling device 200 includes a cover 202 integrally formed with a peripheral wall 204 and provided with a cooled portion 206 onto which electronic components (not shown) can be mounted.

The cooling device 200 also includes a circuit board receiving bay 210 configured and sized to receive an electric circuit board (not shown) so that the undersurface of the circuit board is in direct contact with the cooling fluid to thereby remove the cover interface between the parts to be cooled and the cooling medium.

More specifically, the bay 210 includes an inlet 212, an outlet 214, a chamber 216 defining a cooling fluid path where cooling fluid is brought in contact with the underside of the electric circuit, an inner seal 218, an outer seal 220 a peripheral channel 219 and a leak bypass 222.

Both the inlet 212 and the outlet 214 consist of tapered apertures that allow a substantially constant flow of cooling fluid along the entire width of the chamber 216 to thereby cool the entire undersurface of the electric circuit board adequately.

The inner and outer seals 218 and 220 include respective channels and O-rings. The leak bypass 222 is provided between the inner and outer seals 218 and 220 is fluidly connected to the channel 219 and goes through the body of the cooling device.

A plurality of apertures 224 are provided to releasably mount the electric circuit board (not shown) to the cooling device 200 to thereby seal the bay 210.

It is to be understood that the cooling device is not limited in its application to the details of construction and parts illustrated in the accompanying drawings and described hereinabove. The cooling device is capable of other embodiments and of being practiced in various ways. It is also to be understood that the phraseology or terminology used herein is for the purpose of description and not limitation. Hence, although the present cooling device has been described hereinabove by way of illustrative embodiments thereof, it can be modified, without departing from the spirit, scope and nature of the subject invention.

What is claimed is:

1. A cooling device for an electric circuit; said cooling device comprising:
a body;
a cover so configured and sized to be mounted to the body, the cover defining, with the body, a fluid cooling path;
inner and outer seals provided between the cover and the body to prevent fluid from egressing the fluid cooling path;
wherein one of the body and cover is provided with a leak bypass, provided between the inner and outer seals, that collects and channels leaking fluid.

2. The cooling device of claim 1, wherein the leak bypass includes a channel provided in one of the body and cover.

3. The cooling device of claim 2, wherein the channel goes around the fluid cooling path.

4. The cooling device of claim 1, wherein the inner and outer seals each include a projection provided on one of the body and cover; a corresponding channel provided on the other of the body and cover and a sealing material provided between the projection and the channel.

5. The cooling device of claim 4, wherein the sealing material includes an O-ring.

6. The cooling device of claim 1, wherein the cover and the body both include an electric circuit receiving surface.

7. The cooling device of claim 1, wherein the leak bypass includes a aperture through the body of the cooling device.

8. The cooling device of claim 1, wherein the leak bypass includes a lateral aperture provided in either one of the cover and the body.

9. The cooling device of claim 8, wherein the outer seal is discontinuous.

10. The cooling device of claim 1, wherein the cover includes a circuit receiving bay configured and sized to receive a circuit board; the circuit bay including inner and outer seals and a leak bypass provided between the inner and outer seals.

11. The cooling device of claim 10, wherein the circuit receiving bay also includes a channel provided between the inner and outer seals; the channel being associated with the leak bypass.

12. The cooling device of claim 10, wherein the inner and outer seals each includes a channel and sealing material provided in the channel.

13. The cooling device of claim 12, wherein the sealing material includes an O-ring.

14. The cooling device of claim 10, further comprising a fluid receiving chamber including a cooling fluid inlet and a cooling fluid outlet; the fluid receiving chamber defining a cooling fluid path between the fluid inlet and the fluid outlet.

15. The cooling device of claim 14, wherein the fluid inlet and the fluid outlet are tapered.
